(19) United States
(12) Patent Application Publication
(10) Pub. No.: US 2026/0314439 A1
(43) Pub. Date: Oct. 8, 2026

(54) GROUNDED LEADS IN A QUAD-FLAT PACKAGE

(71) Applicant: STMicroelectronics International N.V., Geneva (CH)

(72) Inventor: Mohd Ridwan BIN JOHARI, Merlimau (MY)

(21) Appl. No.: 19/553,624

(22) Filed: Mar. 2, 2026

Related U.S. Application Data
(60) Provisional application No. 63/782,164, filed on Apr. 2, 2025.

(51) Int. Cl. H10W 70/40

(52) U.S. Cl. CPC H10W 70/466; H10W 70/411; H10W 70/458

(57) ABSTRACT

An example lead-frame, a lead-frame package, and a method for grounding a lead in a lead-frame package are provided. The example lead-frame includes an electrically grounded tie bar, a plurality of leads, an insulating adhesive material, and a conductive material. The plurality of leads, includes at least a grounded lead and an intervening lead, wherein the intervening lead is positioned between the grounded lead and the tie bar. The insulating adhesive material is attached to a surface of the intervening lead. The conductive material is positioned on a surface of the insulating adhesive material opposite the intervening lead, wherein the conductive material electrically connects the grounded lead to the tie bar.

### CROSS-REFERENCE TO RELATED APPLICATIONS

This application claims the benefit of U.S. Provisional Patent Application No. 63/782,164, entitled “GROUNDED LEADS IN A QUAD-FLAT PACKAGE,” which was filed Apr. 02, 2025, the entirety of which is hereby incorporated by reference.

### TECHNOLOGICAL FIELD

Embodiments of the present disclosure relate generally to lead-frames of quad-flat packages, and more particularly, to grounding leads of a lead-frame in a quad-flat package.

### BACKGROUND

Many electronic systems utilize printed circuit boards (PCBs) to support and connect the various electrical components of the electrical system. For example, a PCB may include a rigid structure with a plurality of mount regions configured to receive various electrical components. The PCB may further include conductive traces or paths to enable electrical connections between the various electrical components. A PCB may commonly receive surface-mounted and/or socketed electrical components, including various integrated circuits (ICs).

One example structure for connecting an IC to a PCB is a lead-frame package. A lead-frame package is a surface-mount technology providing structural support for an IC, protection from environmental factors, and an electrical connection between the PCB and the IC without through holes. Conductive protrusions (leads) form electrical connections between the IC in the lead-frame package and the PCB. In some examples, one or more leads of a quad-flat package may need to be electrically grounded.

Applicant has identified many technical challenges and difficulties associated with grounding leads in a quad-flat package. Through applied effort, ingenuity, and innovation, Applicant has solved problems related to grounding leads in a quad-flat package by developing solutions embodied in the present disclosure, which are described in detail below.

### BRIEF SUMMARY

Various embodiments are directed to an example lead-frame, a lead-frame package, and a method for grounding a lead in a lead-frame package.

An example lead-frame is provided. The example lead-frame comprising an electrically grounded tie bar, a plurality of leads, an insulating adhesive material, and a conductive material. The plurality of leads, including at least a grounded lead and an intervening lead, wherein the intervening lead is positioned between the grounded lead and the tie bar. The insulating adhesive material attached to a surface of the intervening lead. The conductive material positioned on a surface of the insulating adhesive material opposite the intervening lead, wherein the conductive material electrically connects the grounded lead to the tie bar.

In some embodiments, the lead-frame further comprises a die pad, wherein the die pad is electrically grounded.

In some embodiments, the tie bar is electrically connected to the die pad.

In some embodiments, the tie bar is substantially parallel to the plurality of leads.

In some embodiments, the insulating adhesive material is a polyimide film.

In some embodiments, the conductive material is an adhesive.

In some embodiments, the conductive material is a copper foil tape.

In some embodiments, the lead-frame is integrated in a quad-flat package.

An example method for grounding a grounded lead in a lead-frame package is further provided. The example method comprising providing a lead-frame. The lead-frame comprising a an electrically grounded tie bar, a plurality of leads, an insulating adhesive material, and a conductive material. The plurality of leads, including at least the grounded lead and an intervening lead, wherein the intervening lead is positioned between the grounded lead and the tie bar. The example method further comprising attaching an insulating adhesive material to a surface of the intervening lead and positioning a conductive material on a surface of the insulating adhesive material opposite the intervening lead, wherein the conductive material electrically connects the grounded lead to the tie bar.

In some embodiments, the lead-frame further comprises a die pad, wherein the die pad is electrically grounded.

In some embodiments, the tie bar is electrically connected to the die pad.

In some embodiments, the tie bar is substantially parallel to the plurality of leads.

In some embodiments, the insulating adhesive material is a polyimide film.

In some embodiments, the conductive material is an adhesive.

In some embodiments, the conductive material is a copper foil tape.

In some embodiments, the lead-frame is integrated in a quad-flat package.

An example lead-frame package is further provided. The example lead-frame package comprising an electrically grounded die pad, an integrated circuit attached to the die pad, and a lead-frame. The lead-frame comprising a tie bar electrically connected to the die pad, a plurality of leads, an insulating adhesive material, and a conductive material. The plurality of leads, including at least a grounded lead; and an intervening lead, wherein the intervening lead is positioned between the grounded lead and the tie bar. The insulating adhesive material attached to a surface of the intervening lead. The conductive material positioned on a surface of the insulating adhesive material opposite the intervening lead, wherein the conductive material electrically connects the grounded lead to the tie bar.

In some embodiments, the lead-frame package further comprises a bond wire electrically connecting the intervening lead to the integrated circuit.

In some embodiments, the insulating adhesive material is a polyimide film.

In some embodiments, the lead-frame package comprises a quad-flat package.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 depicts a perspective view of an example lead-frame package in accordance with an example embodiment of the present disclosure.

FIG. 2 depicts a cross-section view of an example lead-frame package in accordance with an example embodiment of the present disclosure.

FIG. 3 depicts a top view of a grounded lead of an example lead-frame in accordance with an example embodiment of the present disclosure.

FIG. 4 depicts a cross-section view of a grounded lead in accordance with an example embodiment of the present disclosure.

FIG. 5 depicts a manufacturing flow diagram of an example process for grounding a lead in a lead-frame package before downset in accordance with an example embodiment of the present disclosure.

FIG. 6 depicts a manufacturing flow diagram of an example process for grounding a lead in a lead-frame package after downset in accordance with an example embodiment of the present disclosure.

FIG. 7 depicts an example process for grounding a lead of a lead-frame in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

### Overview

Various example embodiments address technical problems associated with grounding a lead of a lead-frame package, such as a quad-flat package. As understood by those of skill in the field to which the present disclosure pertains, there are numerous example scenarios in which an electrical system may benefit from improved techniques for grounding individual leads of a lead-frame in a lead-frame package.

For example, many electronic systems utilize printed circuit boards (PCBs) to support and connect the various electrical components of the electrical system. For example, a PCB may include a rigid structure with a plurality of mount regions configured to receive various electrical components. The PCB may further include conductive traces or paths to enable electrical connections between the various electrical components. A PCB may commonly receive surface-mounted and/or socketed electrical components, including various integrated circuits (ICs) enclosed in surface-mounted and/or socketed packages.

One example structure for connecting an IC to a PCB is a lead-frame package. A lead-frame package is a surface-mount technology providing structural support for an IC, protection from environmental factors, and an electrical connection between the PCB and the IC without through holes. Conductive protrusions (leads) form electrical connections between the IC in the lead-frame package and the PCB. In some examples, one or more leads of a quad-flat package may be electrically grounded. Grounding leads of a lead-frame package may be essential to the operation of an IC and/or the lead-frame package.

In some previous examples, leads to be grounded may be directly connected to a die pad of a lead-frame package. However, in general, the die pad is at a much lower position compared to the inner portion of the leads of the lead-frame package (e.g., on a different plane). As such, making direct connections between the inner lead and the die pad may be difficult, for example, requiring the individual leads to be grounded to the downset die pad post manufacturing. In addition, the requirements for grounded leads may be different based on the application. Directly connecting the grounded leads to the die pad may be very expensive in terms of manufacturing costs, particularly in an instance in which there are numerous custom variations.

In other examples, a grounded bus bar may run perpendicular to the inner leads between the inner leads and the IC. Any inner lead to be grounded may be attached to the grounded bus bar. However, a grounded bus bar may occupy area between the inner leads and the IC, increasing the size of the lead-frame package. In addition, the length of the bond wires may be required to be increased to reach the IC, leading to an increase in cost of the overall package.

The various example embodiments described herein utilize various techniques to electrically ground a lead in a lead-frame package. For example, in some embodiments, an insulating adhesive material is attached to the surface of each lead (e.g., intervening lead) between a lead to be grounded (e.g., grounded lead) and an electrically grounded conductor (e.g., tie bar). Once the insulating adhesive material is attached, a conductive material is attached to the top surface of the insulating adhesive material. Thus, the insulating adhesive material provides electrical insulation between the intervening leads and the conductive material. Applying the insulating adhesive material to the intervening leads enables the intervening leads to continue to transmit electrical signals between the IC and an electrical system, while electrically grounding the grounded lead to the tie bar. In some embodiments, the conductive material comprises an adhesive material, for example, a copper foil tape, which is attached to the top surface of the insulating adhesive material.

As a result of the example embodiments described herein, the cost and complexity of grounding leads in a lead-frame package may be greatly reduced. In addition, less area may be dedicated to the grounding of leads in the lead-frame package. Further, the concepts described herein may provide flexibility in the grounding of leads in a lead-frame package throughout varying points of the manufacturing process.

### Exemplary Systems and Apparatuses

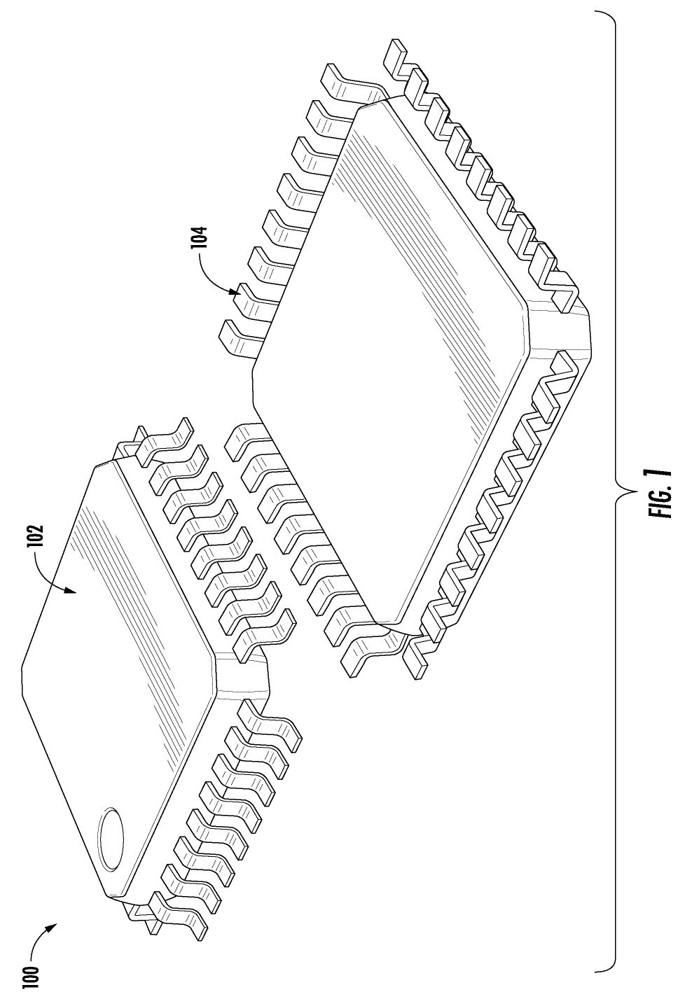

Referring now to FIG. 1, an example quad-flat package 100 is provided. The quad-flat package 100 depicted in FIG. 1 represents one example embodiment of a lead-frame package. As depicted in FIG. 1, the quad-flat package 100 comprises a package molding 102 protecting the internal electrical components of the quad-flat package 100. In addition, the quad-flat package 100 comprises a plurality of leads 104 configured to electrically connect the quad-flat package 100 to an electrical system.

A quad-flat package 100 is a type of lead-frame package used to provide a surface mount for an IC die. A quad-flat package 100 comprises leads 104 extending from all four sides. A quad-flat package 100 is commonly used in electronic devices due to its compact design and efficient heat dissipation. The leads 104 of a quad-flat package 100 are typically thin and closely spaced, making quad-flat packages 100 well-suited for high-density electrical systems. Quad-flat packages 100 may also comprise low-profile quad-flat packages and thin quad-flat packages.

As depicted in FIG. 1, the quad-flat package 100 includes a package molding 102. The package molding 102 comprises any non-conductive material configured to protect the internal components of the quad-flat package 100 from a surrounding environment, for example, an IC. In some embodiments, the quad-flat package 100 may mounted within an electrical system in a harsh environment (e.g., high temperatures, low temperatures, exposed to dirt, water, dust, sand, etc.). In such an example, the quad-flat package 100 may be utilized to protect an IC from the harsh environment during operation. In one non-limiting example, a quad-flat package 100 may be deployed with an electrical system in a portion of an automobile (e.g., engine, chassis, driveline, etc.). The package molding 102 may comprise a resin, polymer plastic, or other insulating material.

As depicted in FIG. 1, the package molding 102 is formed to define the outer dimensions of the quad-flat package 100. The conductive leads 104 protrude from a surface of the quad-flat package to provide a conductive path from an external electrical system to the electrical components of the quad-flat package 100, for example, an IC.

As further depicted in FIG. 1, the quad-flat package 100 comprises a plurality of conductive leads 104. A conductive lead 104 is any conductive protrusion, wire, or surface configured to provide an electrical connection to the internal components of a quad-flat package 100 (e.g., an IC). In some embodiments, a conductive lead 104 may comprise copper, copper alloys, iron, tin, aluminum, or other similar electrically conductive material. The conductive leads 104 may be electrically coupled to distinct electrical components of the quad-flat package 100. For example, one conductive lead 104 may be electrically coupled to a clock, another may be electrically coupled to a reset signal, a third may be electrically coupled to an output signal of the internal IC, a fourth conductive lead 104 may comprise an electrical ground, and so on. The conductive leads 104 may be positioned to align with one or more conductive pads on the mounting surface of an electrical system (e.g., a PCB). The conductive leads 104 may enable a quad-flat package 100 to be electrically coupled to an electrical system utilizing surface-mount technologies, socket-mount technologies, or other similar mount technologies.

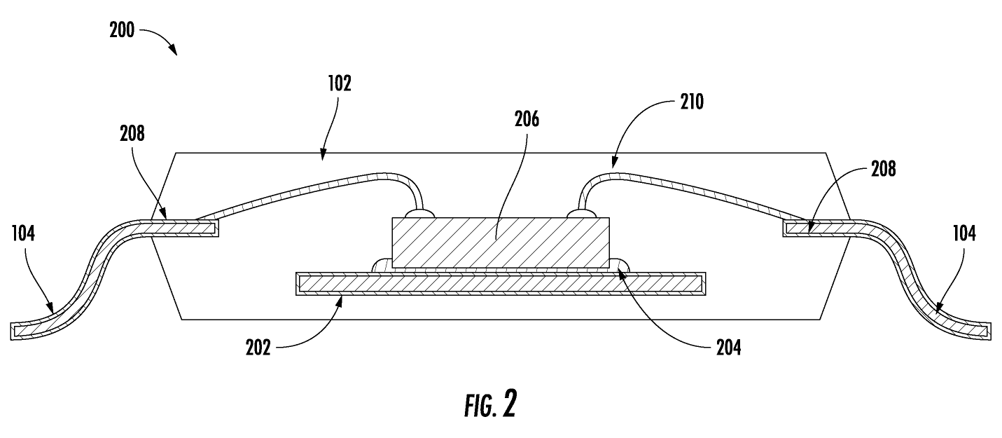

Referring now to FIG. 2, a cross-section view of an example quad-flat package 200 is provided. As depicted in FIG. 2, the example quad-flat package 200 comprises an IC die 206 attached to a die pad 202 with a die attach substance 204. The quad-flat package 200 further includes a plurality of leads 104 electrically connected to the IC die 206 via an internal lead 208 portion of the conductive lead 104. The package molding 102 provides protection to the IC die 206 and other internal components while defining the outer dimensions of the quad-flat package 200.

As depicted in FIG. 2, the example quad-flat package 200 includes an IC die 206. An IC die 206 (e.g., semiconductor die) is any circuitry including semiconductor material utilizing electrical components to perform one or more functions. An IC die 206 may include a processor, reconfigurable fabric, passive electrical components, active electrical components, memory, communications circuitry, and/or any other electrical components necessary to perform the functionality of the IC die 206. An IC die 206 is further configured to receive and/or generate one or more electrical signals. The one or more electrical signals are transmitted between the IC die 206 and an electrical system through one or more IC contact points on the surface of the IC and corresponding conductive leads 104 electrically connected by conductive bond wires 210 to the IC die 206. As depicted in FIG. 2, the one or more conductive leads 104 provide a conductive path to interface with the IC die 206 from an external system.

As depicted in FIG. 2, the example quad-flat package 200 includes a die pad 202. The die pad 202 comprises any thermally conductive material configured to transfer heat from the lead-frame package 100 to a fluid (e.g., air, liquid coolant) in the surrounding environment and/or to a thermal dissipation region of a mounting surface (e.g., PCB). A die pad 202 may comprise copper, aluminum, aluminum alloys, or other similar thermally conductive material. The material comprising a die pad 202 may depend on the application, heat intensity, production method, budget, and other factors. A die attach substance 106 is any bonding substance configured to enable a thermally conductive interface between the IC die 206 and the die pad 202. The die attach substance 106 enables the transfer of heat from the IC die 206 to the die pad 202. The die pad 202 is further thermally connected to a thermal conductive surface 110. The thermal conductive surface 110 is designed to interface with a thermal dissipation region of a mounting interface. The thermal conductive surface 110 enables efficient transfer of heat from the IC die 206 to a surrounding environment.

As depicted in FIG. 2, the example quad-flat package 200 includes a plurality of bond wires 210. Conductive bond wires 210 electrically connect IC contact points on the IC die 206 to corresponding internal lead 208 portions of the conductive leads 104. The conductive bond wires 210 enable the transmission of electrical signals from the IC die 206 to an external electrical system. Bond wires 210 may comprise any conductive material, such as gold, aluminum, copper, and so on. Bond wires 210 may be created using wire drawing or other similar techniques. Common bond wire techniques include ball bonding and wedge bonding.

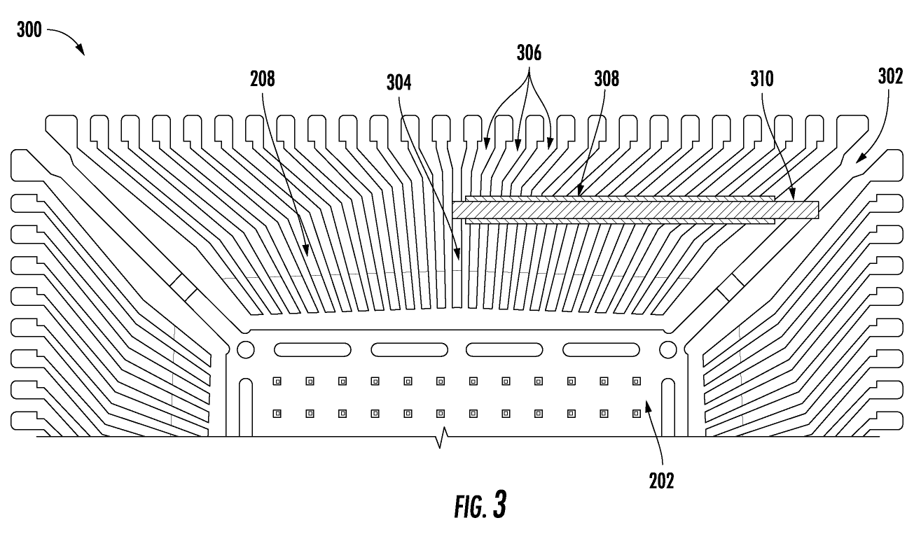

Referring now to FIG. 3, an example lead-frame 300 comprising a grounded lead 304 in accordance with one or more example embodiments of the present disclosure is provided. As depicted in FIG. 3, the lead-frame 300 comprises a plurality of internal leads 208 extending toward the die pad 202. The lead-frame 300 further includes an electrically grounded tie bar 302 connected to the die pad 202. An insulating adhesive material 308 is attached to the surface of a plurality of intervening leads 306 positioned between the tie bar 302 and a grounded lead 304. In addition, a conductive material 310 is placed on a surface of the insulating adhesive material 308 such that the insulating adhesive material 308 electrically insulates the conductive material 310 from each of the intervening leads 306, while the conductive material 310 electrically connects the grounded lead 304 to the electrically grounded tie bar 302.

As depicted in FIG. 3, the example lead-frame 300 comprises a plurality of internal leads 208, a tie bar 302, and a die pad 202. An internal lead 208 comprises a conductive portion of a lead (e.g., lead 104 as depicted in FIGS. 1 - 2), within the package molding (e.g., package molding 102). As depicted in FIG. 3, the lead-frame 300 comprises a plurality of internal leads 208 traversing from an outer edge of a quad-flat package toward the die pad 202. As further depicted in FIG. 2, each of the internal leads 208 are substantially parallel, such that neighboring internal leads 208 do not intersect as they traverse from the external of the quad-flat package toward the internal die pad 202. The internal leads 208 provide an electrically conductive path from the interior of the quad-flat package to the external leads.

The internal leads 208 comprise a grounded lead 304. A grounded lead 304 is any internal lead 208 they may be electrically grounded to support the functionality of the quad-flat package and/or IC die. Although only one grounded lead 304 is depicted, a lead-frame 300 may include a plurality of grounded leads 304. Each grounded lead 304 should be electrically connected to a grounded conductor for proper operation.

As further depicted in FIG. 3, the tie bar 302 traverses parallel to the internal leads 208 from an outer portion of the lead-frame 300 to physically and electrically connect to the die pad 202. The tie bar 302 comprises any conductive portion of the lead-frame 300 designed to provide structural support to the die pad 202 of the lead-frame 300 by attaching between the outer portion of the lead-frame 300 and the die pad 202. The tie bar 302 and die pad 202 are further electrically grounded conductors. Thus, attaching a conductive material (e.g., conductive material 310) to the tie bar 302 electrically grounds any electrically connected components.

In some embodiments, one or more intervening leads 306 may be positioned between a grounded lead 304 and a tie bar 302. An intervening lead 306 comprises any internal lead 208 positioned between a grounded lead 304 and a tie bar 302.

Although not apparent from FIG. 3, the die pad 202 is downset from the internal leads 208. Thus, the die pad 202 is on another plane from the internal leads 208. Because of the downset distance between the die pad 202 and the internal leads 208, it may be difficult to electrically connect an individual internal lead 208 directly to the die pad 202. Thus, to electrically ground a grounded lead 304, a conductive path may be established between the grounded lead 304 and the tie bar 302.

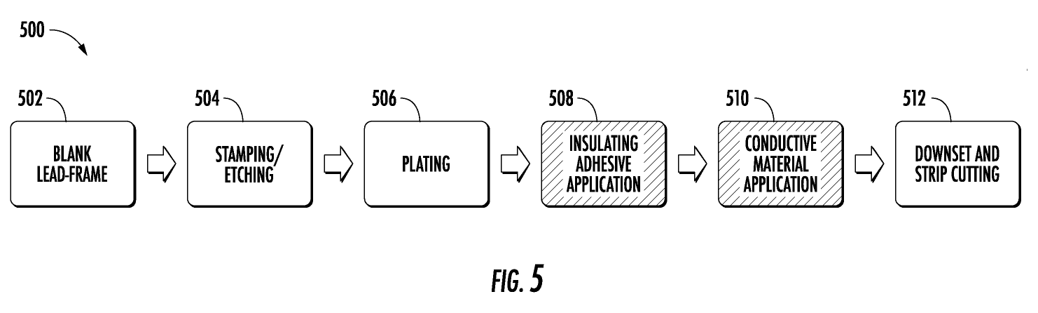

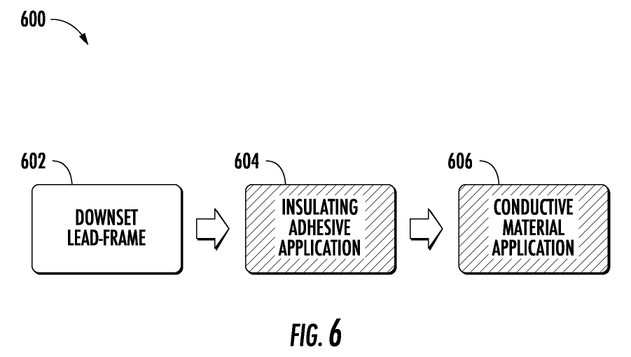

As further depicted in FIG. 3, the example lead-frame 300 utilizes an insulating adhesive material 308 to electrically insulate the intervening leads 306 from the conductive material 310. An insulating adhesive material 308 may comprise any electrical insulator that may adhere to a surface of an internal lead 208. In one non-limiting example, an insulating adhesive material 308 may comprise a polyimide film. The insulating adhesive material 308 may be attached to the surfaces of one or more consecutive intervening leads 306. The insulating adhesive material 308, enables the intervening leads 306 to continue transmitting electrical signals between the IC die and the leads without interruption or disruption from the conductive material 310. As described in relation to FIG. 5, in some embodiments, the insulating adhesive material 308 may be applied by a supplier before strips of lead-frames are cut. As described in relation to FIG. 6, in some embodiments, the insulating adhesive material 308 may be applied by a lead-frame customer after the lead-frame 300 has been downset.

As further depicted in FIG. 3, a conductive material 310 is positioned on top of the insulating adhesive material 308 (on a surface of the insulating adhesive material 308 opposite the intervening lead 306) and electrically connects the grounded lead 304 to the electrically grounded tie bar 302. As described herein, a conductive material 310 comprises any electrically conductive material that may be positioned on top of the insulating adhesive material 308. In some embodiments, the conductive material 310 may be narrower than the insulating adhesive material 308. In some embodiments, the conductive material 310 may be an adhesive material that may be attached to the surface of the insulating adhesive material 308. For example, in some embodiments, the conductive material 310 may comprise copper foil tape.

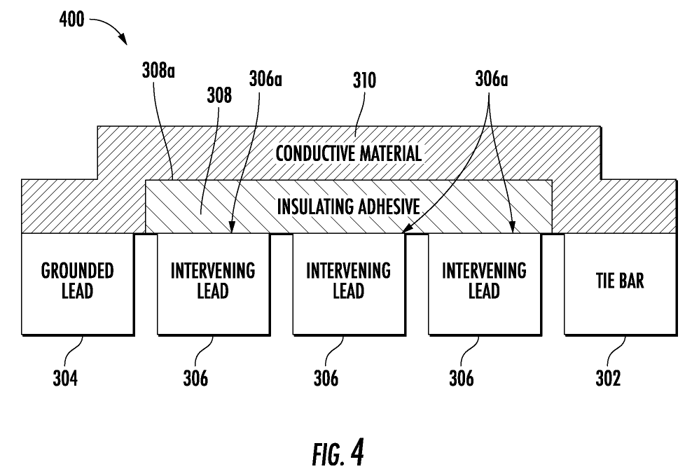

Referring now to FIG. 4, a cross-section view of a lead-frame portion 400 is depicted. As depicted in FIG. 4, the lead-frame portion 400 comprises a grounded lead 304 and a tie bar 302 separated by a plurality of intervening leads 306. Each intervening lead 306 may be configured to transmit electrical signal between an IC die and external leads. As further depicted in FIG. 4, an insulating adhesive material 308 is placed on a surface (e.g., top surface 306a) of each intervening lead 306 between the grounded lead 304 and the tie bar 302. A conductive material 310 is placed on top of the insulating adhesive material 308 (e.g., top surface 308a) and electrically connects the grounded lead 304 to the electrically grounded tie bar 302. The insulating adhesive material 308 electrically insulates the intervening leads 306 from the conductive material 310, enabling the intervening leads 306 to continue to transmit and receive signals.

### Exemplary Methods

Referring now to FIG. 5, an example manufacturing flow diagram depicting an example process 500 for grounding a lead (e.g., grounded lead 304) in a lead-frame package (e.g., quad-flat package 100) before downset is provided.

As depicted in FIG. 5, at block 502, a blank lead-frame is provided. A blank lead-frame comprises a flat sheet of conductive material, for example, a copper alloy, often in a square or rectangular shape.

At block 502, a stamping and etching process is performed. Stamping is a manufacturing process that shapes the blank lead-frame sheet into a lead-frame by pressing the blank lead-frame into a mold. In some embodiments, a heavy plate containing the stamp die set may be stamped on the blank lead-frame sheet, defining the structures of the lead-frame. Stamping may produce lead-frames with precise dimensions and shapes.

Etching is a manufacturing process that utilizes chemicals to create precise patterns on the stamped lead-frame sheets. In some embodiments, etching may include applying a layer of photoresist to the blank and/or stamped lead-frame, aligning a photomask with the desired pattern over the photoresist, exposing the photoresist to ultraviolet light in the desired pattern, exposing the portions of the lead-frame to be etched, and immersing the lead-frame in a chemical etching solution. The etching process may enable precise shapes and structures to be defined in the lead-frame.

At block 506, a plating process is performed. Plating is a process that involves applying a conductive coating to the lead-frame, for example, nickel, silver, gold, tin, palladium, etc. Plating may improve adhesion of wire bonds, package molding, and die attach substances. Plating may also improve adhesion of the insulating adhesive material (e.g., insulating adhesive material 308). Plating processes may be referred to as electroplating.

At block 508, the insulating adhesive material is applied. One or more strips of insulating adhesive material may be applied to any intervening internal leads (e.g., intervening leads 306) between a grounded lead (e.g., grounded lead 304) and a tie bar (e.g., tie bar 302). In some embodiments, an intervening lead that is also a grounded lead may be skipped, such that insulating adhesive material is not applied. Insulating adhesive material may be applied automatically, for example by a robot or machine configured to apply the insulating adhesive material to the intervening leads. Although depicted as a continuous strip, in some embodiments, the insulating adhesive material may comprise discrete portions placed on the surface of each intervening lead.

At block 510, the conductive material (e.g., conductive material 310) may be applied to a surface of the insulating adhesive material opposite the intervening leads and electrically attach the grounded leads to the tie bar. Thus, the conductive material may create an electrical connection between the grounded lead and the tie bar, electrically grounding the grounded lead. In some embodiments, the conductive material may traverse across multiple grounded leads and insulating adhesive materials to electrically ground a plurality of grounded leads. In some embodiments, the conductive material may be an adhesive material, such as copper foil tape. The conductive material may be applied automatically, for example by a robot or machine configured to apply the conductive material to the surface of the insulating adhesive material on the intervening leads.

At block 512, the downset and strip cutting processes are performed. The downset process is the process by which the die pad (e.g., die pad 202) portion of the lead-frame is pushed downwards relative to the internal leads of the lead-frame such that the lead-frames are properly aligned with an IC die (e.g., IC die 206) attached to the die pad. The strip cutting process is the process by which lead-frames are separated into individual packages. Strip cutting may be performed by a mechanical cutting machine.

Thus, as depicted in FIG. 5, the attachment of the insulating adhesive material and the conductive material for connecting grounded leads to an electrical ground may happen during the manufacturing flow, for example, before the lead-frame is downset and the lead-frames are cut into strips.

Referring now to FIG. 6, an example manufacturing flow diagram depicting an example process 600 for grounding a lead (e.g., grounded lead 304) in a lead-frame package (e.g., quad-flat package 100) after downset is provided. As depicted in FIG. 6, in some embodiments, a grounded lead may be grounded after the lead-frame has been downset by a manufacturer, for example, at a customer site.

At block 602, a downset lead-frame is provided. A downset lead-frame has already undergone a downset process during which the die pad (e.g., die pad 202) portion of the lead-frame is pushed downwards relative to the internal leads of the lead-frame such that the lead-frames are properly aligned with an IC die (e.g., IC die 206) attached to the die pad.

At block 604, the insulating adhesive material (e.g., insulating adhesive material 308) is applied, insulating any intervening leads from the conductive material.

At block 606, the conductive material (e.g., conductive material 310) may be applied to electrically connect a grounded lead to an electrically grounded tie bar. The conductive material is applied to a surface of the insulating adhesive material opposite the intervening leads such that the intervening leads are electrically insulated from the conductive material. In some embodiments, the conductive material may be applied automatically, for example by a robot or machine configured to apply the conductive material to the surface of the insulating adhesive material on the intervening leads.

Thus, as depicted in FIG. 6, the attachment of the insulating adhesive material and the conductive material for connecting grounded leads to an electrical ground may occur at a customer site, after the lead-frame is downset and the lead-frames are cut into strips.

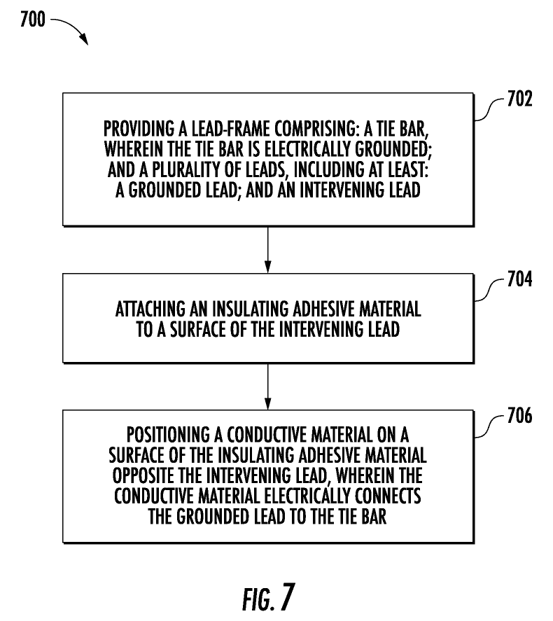

Referring now to FIG. 7, example process 700 for grounding a lead (e.g., grounded lead 304) of a lead-frame (e.g., lead-frame 300) is provided. At block 702, a lead-frame comprising an electrically grounded tie bar (e.g., tie bar 302) and a plurality of leads (e.g., internal leads 208) is provided. The plurality of leads, including at least the grounded lead; and an intervening lead (e.g., intervening lead 306). Wherein the intervening lead is positioned between the grounded lead and the tie bar. In some embodiments, the lead-frame may already be downset and strip cut, such that a die pad (e.g., die pad 202) is on a different plane than the plurality of leads. In some embodiments, the lead-frame may be provided before the downset and strip cutting processes are performed.

At block 704, an insulating adhesive material (e.g., insulating adhesive material 308) is attached to a surface (e.g., top surface 306a) of the intervening lead. In some embodiments, the insulating adhesive material may be applied automatically, for example by a robot or machine configured to apply the insulating adhesive material to the intervening leads.

At block 706, a conductive material (e.g., conductive material 310) is positioned on a surface (e.g., top surface 308a) of the insulating adhesive material opposite the intervening lead. The conductive material electrically connects the grounded lead to the tie bar. The conductive material may be positioned automatically, for example by a robot or machine configured to apply the conductive material to the surface of the insulating adhesive material on the intervening leads. In some embodiments, the conductive material may comprise an adhesive material, attaching the conductive material to the top surface of the insulating adhesive material. Positioning the conductive material electrically connecting the grounded lead and the tie bar on the top surface of the insulating adhesive material, enables an electrical connection between the tie bar and the grounded lead to be made without disrupting the flow of signals through each of the intervening leads.

### Conclusion

While this detailed description has set forth some embodiments of the present invention, the appended claims cover other embodiments of the present invention which differ from the described embodiments according to various modifications and improvements. For example, one skilled in the art may recognize that such principles may be applied to any lead-frame package for which leads may be grounded during operation.

Within the appended claims, unless the specific term “means for” or “step for” is used within a given claim, it is not intended that the claim be interpreted under 35 U.S.C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A lead-frame comprising:
a tie bar, wherein the tie bar is electrically grounded;
a plurality of leads, including at least:
a grounded lead; and
an intervening lead, wherein the intervening lead is positioned between the grounded lead and the tie bar;
an insulating adhesive material attached to a surface of the intervening lead; and
a conductive material positioned on a surface of the insulating adhesive material opposite the intervening lead;

2. The lead-frame of claim 1, further comprising a die pad, wherein the die pad is electrically grounded.

3. The lead-frame of claim 2, wherein the tie bar is electrically connected to the die pad.

4. The lead-frame of claim 1, wherein the tie bar is substantially parallel to the plurality of leads.

5. The lead-frame of claim 1, wherein the insulating adhesive material is a polyimide film.

6. The lead-frame of claim 1, wherein the conductive material is an adhesive.

7. The lead-frame of claim 6, wherein the conductive material is a copper foil tape.

8. The lead-frame of claim 1, wherein the lead-frame is integrated in a quad-flat package.

9. A method for grounding a grounded lead in a lead-frame package, the method comprising:
providing a lead-frame comprising:
a tie bar, wherein the tie bar is electrically grounded; and
a plurality of leads, including at least:
the grounded lead; and
an intervening lead, wherein the intervening lead is positioned between the grounded lead and the tie bar;
attaching an insulating adhesive material to a surface of the intervening lead; and
positioning a conductive material on a surface of the insulating adhesive material opposite the intervening lead, wherein the conductive material electrically connects the grounded lead to the tie bar.

10. The method of claim 9, wherein the lead-frame further comprises a die pad, wherein the die pad is electrically grounded.

11. The method of claim 10, wherein the tie bar is electrically connected to the die pad.

12. The method of claim 9, wherein the tie bar is substantially parallel to the plurality of leads.

13. The method of claim 9, wherein the insulating adhesive material is a polyimide film.

14. The method of claim 9, wherein the conductive material is an adhesive.

15. The method of claim 14, wherein the conductive material is a copper foil tape.

16. The method of claim 9, wherein the lead-frame is integrated in a quad-flat package.

17. A lead-frame package comprising:
a die pad, wherein the die pad is electrically grounded;
an integrated circuit attached to the die pad;
a lead-frame comprising:
a tie bar, wherein the tie bar is electrically connected to the die pad; and
a plurality of leads, including at least:
a grounded lead; and
an intervening lead, wherein the intervening lead is positioned between the grounded lead and the tie bar;
an insulating adhesive material attached to a surface of the intervening lead; and
a conductive material positioned on a surface of the insulating adhesive material opposite the intervening lead;

18. The lead-frame package of claim 17, further comprising:
a bond wire electrically connecting the intervening lead to the integrated circuit.

19. The lead-frame package of claim 17, wherein the insulating adhesive material is a polyimide film.

20. The lead-frame package of claim 17, wherein the lead-frame package comprises a quad-flat package.
